(19) United States
(12) Patent Application Publication
(10) Pub. No.: US 2020/0119250 A1
(43) Pub. Date: Apr. 16, 2020

(54) IN-SITU FORMATION OF A THERMOELECTRIC DEVICE IN A SUBSTRATE PACKAGING

(71) Applicant: Intel Corporation, Santa Clara, CA (US)

(72) Inventors: Cheng Xu, Chandler, AZ (US); Zhimin Wan, Chandler, AZ (US); Yikang Deng, Chandler, AZ (US); Junnan Zhao, Gilbert, AZ (US); Chong Zhang, Chandler, AZ (US); Ying Wang, Chandler, AZ (US); Kyu-oh Lee, Chandler, AZ (US)

(73) Assignee: Intel Corporation, Santa Clara, CA (US)

(21) Appl. No.: 16/158,188

(22) Filed: Oct. 11, 2018

(51) Int. Cl. H01L 35/32; H01L 35/10; H01L 35/30; H01L 35/34

(52) U.S. Cl. CPC H01L 35/32; H01L 35/34; H01L 35/30; H01L 35/10

(57) ABSTRACT

A semiconductor device package structure is provided. The semiconductor device package structure includes a substrate, a die coupled to the substrate, and a thermoelectric device. The thermoelectric device may include a P-type semiconductor material, a N-type semiconductor material, and a plurality of interconnect structures to transmit current through the P-type and N-type semiconductor material. In an example, the P-type semiconductor material and the N-type semiconductor material may be at least in part embedded within the substrate. The thermoelectric device has a first side proximal to the die, and a second side separated from the die by the first side.

### BACKGROUND

Integrated Circuit (IC) semiconductor device packages are decreasing in size, while becoming more powerful. This has provided a thermal challenge. For example, removing heat from bottom surface of an IC die that is on a substrate can be challenging.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A, 1B, 1C, 1D, 1E, 1F, and 1G schematically illustrate a cross-sectional view (e.g., along X-Z axis) of a semiconductor device package structure that includes a thermoelectric cooling device embedded at least in part within a substrate, e.g., to cool a component coupled to the substrate, according to some embodiments.

FIGS. 2A-2B schematically illustrate a cross-sectional view (e.g., along X-Z axis) of another semiconductor device package structure that includes a thermoelectric cooling device embedded at least in part within a substrate, e.g., to cool a component coupled to the substrate, according to some embodiments.

FIG. 2C illustrates the package of FIGS. 2A-2B, with a thermally conductive underfill material between the component and the thermoelectric cooling device, according to some embodiments.

FIGS. 3A-3B schematically illustrate a cross-sectional view (e.g., along X-Z axis) of another semiconductor device package structure that includes a thermoelectric cooling device embedded at least in part within a substrate, e.g., to cool a component coupled to the substrate, according to some embodiments.

FIG. 3C illustrates the package of FIGS. 3A-3B, with a thermally conductive underfill material between the component and the thermoelectric cooling device, according to some embodiments.

FIGS. 4A, 4B, 4C, 4D, 4E, 4F, 4G, and 4I illustrate example processes for formation of the semiconductor device package structure of any of FIGS. 1A-1G, according to some embodiments.

FIGS. 5A, 5B, 5C, 5D, 5E, 5F, 5G, and 5I illustrate example processes for formation of the semiconductor device package structure of FIGS. 2A-2B, according to some embodiments.

FIGS. 6A, 6B, 6C, 6D, 6E, 6F, and 6G illustrate example processes for formation of the semiconductor device package structure of FIGS. 3A-3B, according to some embodiments.

FIG. 7 illustrates a flowchart depicting a method for forming a semiconductor device package structure that includes a thermoelectric cooling device embedded at least in part within a substrate, e.g., to cool a component coupled to the substrate, according to some embodiments.

FIG. 8 illustrates a computer system, a computing device or a SoC (System-on-Chip), where one or more components of the computing device are included in a semiconductor package that includes a thermoelectric cooling device embedded at least in part within a substrate, e.g., to cool a component coupled to the substrate, according to some embodiments.

### DETAILED DESCRIPTION

In an example, in a semiconductor package, one or more IC dies may be coupled to a substrate. For example, a first or top surface of a die may be facing away from the substrate, and a second or bottom surface of the die may be facing towards the substrate.

It may be a challenge to dissipate heat from the bottom surface of the die (e.g., which is facing the substrate). In some embodiments, to alleviate such thermal issues, the substrate may have an embedded thermoelectric device. The thermoelectric device may include thermoelectric materials, e.g., one or more P-type semiconductor materials, and one or more N-type semiconductor materials, which may be arranged in series. When current is transmitted through the P-type and N-type semiconductor materials of the thermoelectric device, the materials exhibit Peltier effect of thermoelectric material. Due to such effect, the thermoelectric device transfers heat from a cold side to a hot side. For example, the thermoelectric device may be used to transfer heat away from the die, thereby cooling the die. Other technical effects will be evident from the various embodiments and figures.

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” or “some embodiments” means that a particular feature, structure, function, or characteristic described in connection with the embodiment is included in at least one embodiment of the invention. Thus, the appearances of the phrase “in an embodiment” or “in one embodiment” or “some embodiments” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The terms “left,” “right,” “front,” “back,” “top,”“bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

It is pointed out that those elements of the figures having the same reference numbers (or names) as the elements of any other figure can operate or function in any manner similar to that described, but are not limited to such.

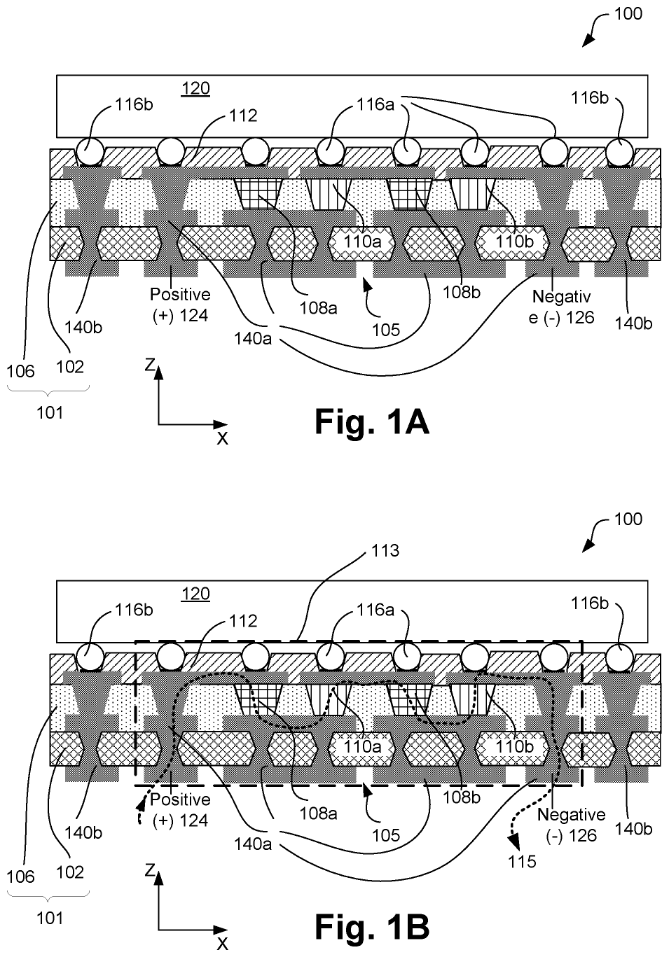

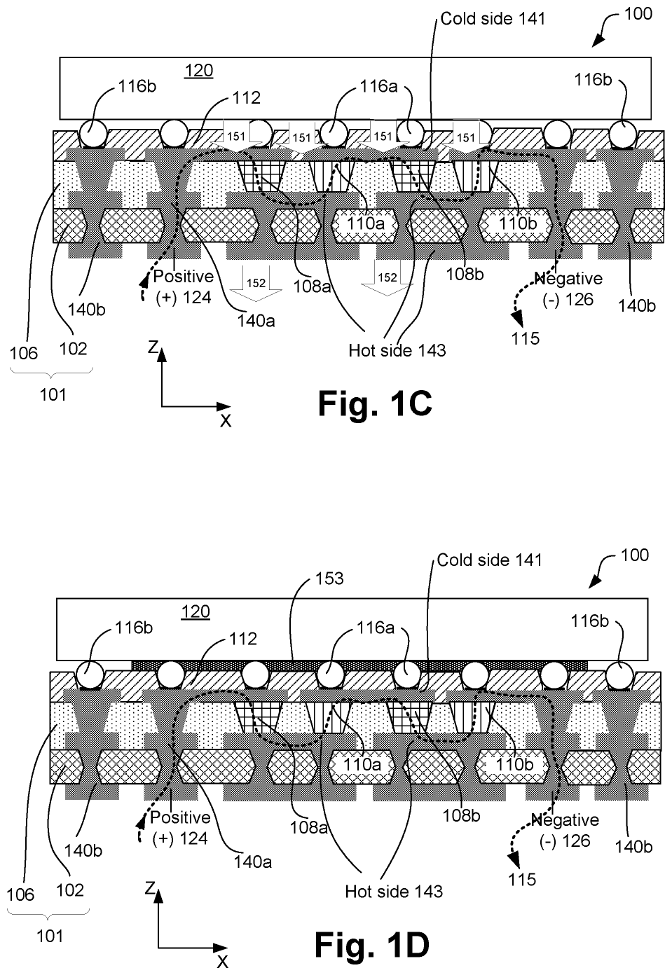

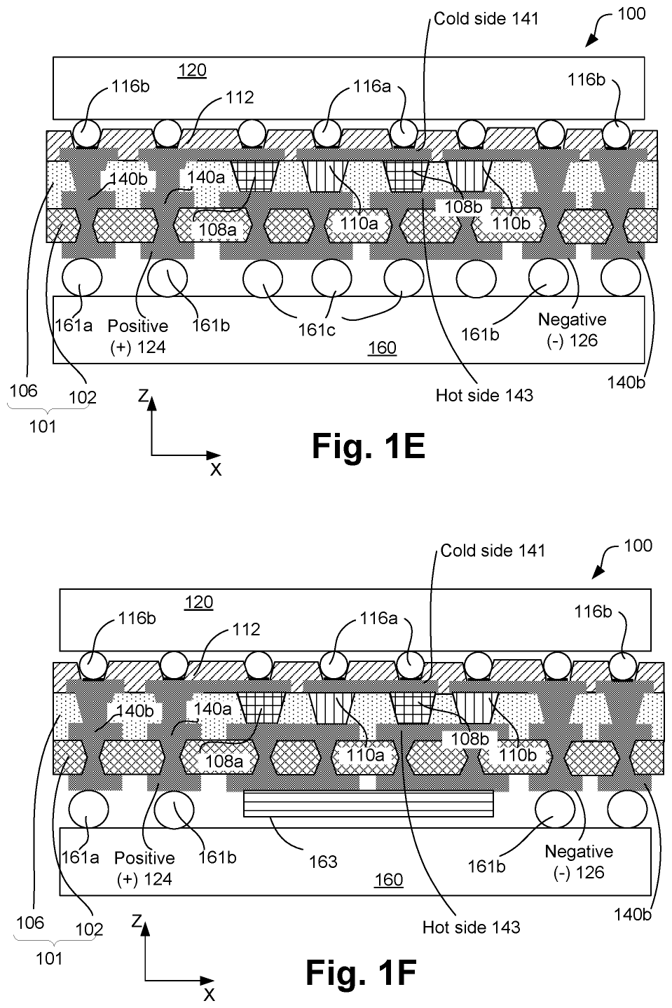

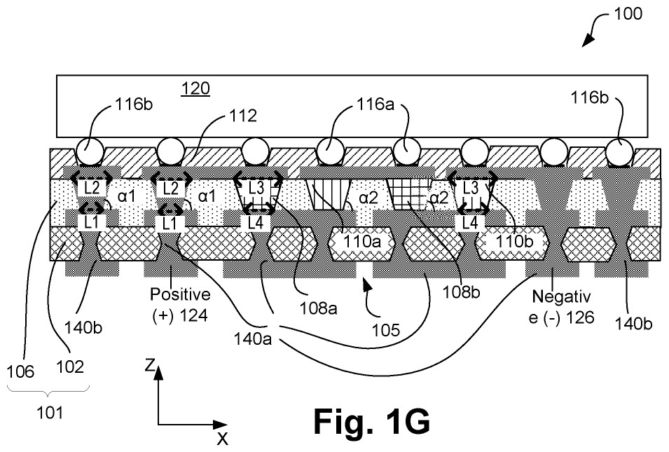

FIG. 1A schematically illustrates a cross-sectional view (e.g., along X-Z axis) of a semiconductor device package structure 100 (also referred to as package 100) that includes a thermoelectric cooling device 105 embedded at least in part within a substrate 101, e.g., to cool a component 120 coupled to the substrate 101, according to some embodiments.

The component 120 can be any electronic device or component that may be included in a semiconductor package, e.g., an Integrated Circuit (IC) die, a chip, a processor, computer memory, platform controller hub, etc. In some embodiments, the component 120 is a discrete chip, a plurality of chips arranged at least in part in a stack over the substrate 101, or the like. The component 120 may include, or be a part of, a processor, memory, or application specific integrated circuit (ASIC), for example. Although merely one component 120 is illustrated, the package 100 may include any other appropriate number of component 120.

The package 100 includes the substrate 101. In some embodiments, the substrate 101 includes a layer 102 including core material (also referred to as core layer 102), and one or more layers 106 of dielectric material.

A substrate discussed herein, such as the substrate 101, may electrically couple an electrical component (e.g., one or more IC dies) and a next-level component to which an IC package (e.g., a circuit board) is coupled. In an example, a substrate may include any suitable type of substrate capable of providing electrical communication between an IC die and an upper IC package coupled with a lower IC/die package. In an example, a substrate may include any suitable type of substrate capable of providing electrical communication between an upper IC package and a next-level component to which an IC package is coupled. A substrate may also provide structural support for a die. By way of example, in one embodiment, a substrate may comprise a multi-layer substrate—including alternating layers of a dielectric material and metal built-up around a core layer (either a dielectric core or a metal core). In another embodiment, a substrate may be a coreless multi-layer substrate. Other types of substrates and substrate materials may also be used (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases). In an example, a substrate is a cored or coreless package substrate, which may include epoxy resins, FR4, one or more semiconductor interposers (e.g., silicon), etc. A substrate may be formed of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, can be used in printed circuit boards (PCBs).

The component 120 is attached to the substrate 101 in any suitable configuration, such as a flip-chip configuration. The component 120 is coupled to the substrate 101 using a first plurality of interconnect structures 116a and a second plurality of interconnect structures 116b, through a solder resist layer 112.

Elements referred to herein with a common reference label followed by a particular number or letter may be collectively referred to by the reference label alone. For example, multiple interconnect structures 116a may be collectively and generally referred to as interconnect structures 116a in plural and interconnect structure 116a in singular; and multiple interconnect structures 116b may be collectively and generally referred to as interconnect structures 116b in plural and interconnect structure 116b in singular. Similarly, interconnect structures 116a, 116b may be collectively and generally referred to as interconnect structures 116 in plural, and interconnect structure 116 in singular.

The interconnect structures 116 for example, are bumps, bump pads, metal pillars (e.g., copper pillars), balls formed using metals, alloys, solderable material, or the like. For example, the interconnect structures 116 are bumps, balls, and/or solder formed using metals, alloys, solderable material, and/or the like.

In some embodiments, the interconnect structures 116a are for thermally coupling the thermoelectric cooling device 105 (also referred to as device 105) to the component 120. For example, the interconnect structures 116a may not transmit electrical signals to, or from, the component 120, and merely provides a thermally conductive path between the component 120 and the device 105. Thus, the interconnect structures 116a are electrically dead-ended on the component 120, such that the interconnect structures 116a are electrically isolated from various circuitries within the component 120. The interconnect structures 116a may also be referred to herein as thermal interconnect structures, or as thermal bumps.

In some embodiments, the interconnect structures 116b are for electrically coupling the component 120 to the substrate 101. For example, the interconnect structures 116b transmit electrical signals between the component 120 and the substrate 101. The interconnect structures 116b may also be referred to herein as electrical interconnect structures. Although merely two electrical interconnect structures 116b are illustrated in FIG. 1A, the package 100 may comprise any appropriate number of such electrical interconnect structures.

The package 100 includes a plurality of interconnect structures 140a, and another plurality of interconnect structures 140b. The interconnect structures 140 are, for example, metallization levels embedded within various layers of the substrate 101. The interconnect structures 140 comprise metals, alloys, solderable material, or the like. In some embodiments, individual build-up layer of the layers 106 of the substrate 101 embeds an interconnect or metallization level (i.e., a routing layer) for trace routing and includes a dielectric layer for electrically insulating laterally adjacent traces as well as adjacent interconnect levels (overlying and/or underlying). The interconnect levels form the interconnect structures 140. Thus, the interconnect structures 140 may include conductive vias, solder, traces, metallization levels, routing layers, etc.

In some embodiments, the interconnect structures 140a are included in the 1device 105, and are primarily (or exclusively) for transmitting current to and/or from the device 105. In an example, the interconnect structures 140a are electrically isolated from the component 120. For example, as discussed herein previously, as the interconnect structures 116a are electrically isolated from the component 120, the interconnect structures 140a are also electrically isolated from the component 120.

In some embodiments, the interconnect structures 140b are electrically coupled to the component 120. For example, the interconnect structures 140b transmit signals to, and from, the component 120. For example, the interconnect structures 140b are to communicate signals between the component 120 and a circuit board (not illustrated in FIG. 1A), where the package 100 may be coupled to the circuit board. The interconnect structures 140b are electrically isolated from the interconnect structures 140a.

The package 100 includes the device 105. FIG. 1B illustrates, using dotted lines 113, an approximate boundary of the thermoelectric cooling device 105 of FIG. 1A, according to some embodiments. Referring to FIGS. 1A-1B, the device 105 includes thermoelectric materials 108a, 108b, 110a, 110b. Merely as an example, the thermoelectric materials 108a, 108b are N-type thermoelectric material (the locations of the P and N-type thermoelectric materials may be interchanged, for example, if a direction of current flow through the device 105 is reversed). For example, the P-type thermoelectric materials 108 are doped with P-type impurities, and the N-type thermoelectric materials 110 are doped with N-type impurities. The P-type and N-type thermoelectric materials are arranged in an interleaved manner, as illustrated in the figures.

Any appropriate type of thermoelectric materials 108, 110 may be used. Thermoelectric materials show the thermoelectric effect in a strong or convenient form. The thermoelectric effect refers to phenomena by which either a temperature difference creates an electric potential, or an electric potential creates a temperature difference. These phenomena are known more specifically as the Seebeck effect (converting temperature to current), Peltier effect (converting current to temperature), and Thomson effect (conductor heating/cooling). While all materials have a nonzero thermoelectric effect, in most materials it is too small to be useful. However, low-cost materials that have a sufficiently strong thermoelectric effect (and other required properties) may be used in applications including power generation and refrigeration. A commonly used thermoelectric material in such applications is bismuth telluride (Bi₂Te₃).

A dimensionless parameter figure of merit is used to evaluate thermoelectric material, where the figure of merit zT is given by:

zT=(σ.S².T)/κ Equation b 1

where σ is the electrical conductivity, T is the temperature, κ is the thermal conductivity, S is the Seebeck coefficient. The ability of a given material to efficiently produce thermoelectric power is related to its figure of merit. The higher is the figure of merit, the more effective is the thermoelectric material in producing power (or the more effective is the thermoelectric material in transferring heat in the device 105).

Table 1 below illustrates a figure of merit and a maximum temperature difference for some example thermoelectric materials.

TABLE 1

| | | Max temperature |
|---|---|---|
| | Figure of Merit | difference |
| Bulk Bismuth Telluride Pellets | 2.35 | 64 |
| Bismuth Telluride Ink | 0.9 | 32 |
| TE paint | 1.21 | 40 |
| (Selanylidene(Tellanylidene)Bismuth | | |
| (BiSeTe) particle based) | | |
| Electroplated bismuth Telluride | 0.7 | 30 |
| thin film | | |

In some embodiments, the higher the maximum temperature achievable, the more effective the device 105 is for transferring heat from the component 120. In an example, the higher the Figure of merit of the thermoelectric material used, the higher is the maximum temperature achievable. In an example, for the thermoelectric materials 108, 110, a Figure of merit is at least 0.3 or higher. Any appropriate thermoelectric material (e.g., semiconductor thermoelectric material) may be used for the thermoelectric materials 108, 110, including one or more of the materials listed in Table 1. The scope of this disclosure is not limited by the type of thermoelectric material used in the device 105. The thermoelectric materials 108, 110 are also referred to as semiconductor thermoelectric material, or as semiconductor material.

A positive terminal 124 and a negative terminal 126 of the device 105 is illustrated in FIGS. 1A-1B. FIG. 1B illustrates an example path of flow of current 115 using a dotted line. For example, Direct Current (DC) flows through the device 105, from the positive terminal 124 to the negative terminal 126. The current 115 is transmitted from the positive terminal 124, through the interconnect structures 140a, P-type thermoelectric material 108a, N-type thermoelectric material 110a, P-type thermoelectric material 108b, N-type thermoelectric material 110b, and exits the device 105 through the terminal 126. Any appropriate power source may be used to transmit the current 115 through the device 105. The current 115, which flows through the device 105, is electrically isolated from the component 120, e.g., does not enter or transmit through the component 120.

FIG. 1C illustrates a flow of heat through the thermoelectric cooling device 105 of FIG. 1A, according to some embodiments. The device 105 has a first side 141, and a second opposing side 143, as illustrated in FIG. 1C. In an example, due to the arrangement of the P-type thermoelectric materials 108 and the N-type thermoelectric materials 110 and the flow of current 115, the thermoelectric materials 108, 110 transfer heat from the side 141 to the side 143, e.g., due to the inherent properties of the thermoelectric material (e.g., due to Peltier effect of thermoelectric material). Accordingly, the side 141 is also referred to herein as a “cold side,” and the side 143 is also referred to herein as a “hot side.”

As heat is transferred from the cold side 141 to the hot side 143 of the device 105, heat (e.g., symbolically represented by arrows 151) is removed from the component 120 (e.g., through the interconnect structures 116a) and released on the hot side 143 (e.g., symbolically represented by arrows 152). Thus, the device 105 transfers heat from the component 120, and aids in cooling of the component 120. For example, a bottom surface of the component 120 (e.g., a surface of the component 120 facing the substrate 101) may be cooled by the device 105.

FIG. 1D illustrates the package 100 of FIGS. 1A-1C, with a thermally conductive underfill material 153 between the component 120 and the device 105, according to some embodiments. The thermally conductive underfill material 153 may aid in transfer of heat from the component 120 to the cold side 141 of the device 105.

FIG. 1E illustrates the package 100 of FIGS. 1A-1D coupled to a circuit board 160 (e.g., a printed circuit board or PCB, a motherboard, etc.), according to some embodiments. For example, the package 100 may be coupled to the circuit board 160 through interconnect structures 161.

The interconnect structures 161 for example, are bumps, bump pads, metal pillars (e.g., copper pillars), balls formed using metals, alloys, solderable material, or the like. For example, the interconnect structures 161 are bumps, balls, and/or solder formed using metals, alloys, solderable material, and/or the like.

In some embodiments, the interconnect structures 161 includes interconnect structures 161a for electrically coupling the substrate 101 and the component 120 to the circuit board 160. For example, the interconnect structures 161a transmit electrical signals between the component 120 and the circuit board 160, through the substrate 101 and the interconnect structures 140b.

In some embodiments, the interconnect structures 161 includes interconnect structures 161b for electrically coupling the device 105 to the circuit board 160. For example, the interconnect structures 161b transmit current to the positive terminal 124 from the circuit board 160, and transmit current from the negative terminal 161b of the device 105 to the circuit board 160.

In some embodiments, the interconnect structures 161 includes interconnect structures 161c for thermally coupling the thermoelectric cooling device 105 to the circuit board 160. For example, the interconnect structures 161c may not transmit electrical signals to, or from, the circuit board 160, and merely provides a thermally conductive path between the device 105 and the circuit board 160. Thus, the interconnect structures 161c are electrically dead-ended on the circuit board 160. The interconnect structures 161c may also be referred to herein as thermal interconnect structures, or as thermal bumps. The interconnect structures 161c facilitate propagation of heat from the device 105 to the circuit board 160. Although FIG. 1E illustrates the interconnect structures 161c, in some examples, the interconnect structures 161c may be absent in the package 100.

FIG. 1F illustrates the package 100 of FIGS. 1A-1D coupled to the circuit board 160, wherein a heat spreader 163 is coupled to the package 100, according to some embodiments. FIG. 1F is at least in part similar to the package of FIG. 1E. However, in FIG. 1F, the interconnect structures 161c are replaced by the heat spreader 163. The heat spreader 163 facilitates dissipation of heat from the hot side 143 of the device 105 to the ambient.

A first surface (e.g., a top surface) of the heat spreader 163 is coupled to the hot side 143 (e.g., coupled to the interconnect structures 140a and/or the substrate 101 of the package 100), and an opposing second surface (e.g., a bottom surface) faces the circuit board 160. In some embodiments (and contrary to the illustrations of FIG. 1F), the second surface of the heat spreader 163 is coupled to the circuit board 160 via thermally conductive material, such as Thermal Interface Material (TIM), e.g., thermal grease, thermal adhesive, thermal gap filler, thermally conductive pad, thermal tape, etc. Thus, the empty space in FIG. 1F between the heat spreader 163 and the circuit board 160 may include one or more of the above discussed thermally conductive material.

FIG. 1G illustrates the package 100 of FIGS. 1A-1D, and also illustrates dimensions of various interconnect structures 140, according to some embodiments. As will be discussed herein in further detail, in some embodiments, the interconnect structures 140a, 140b are formed and patterned using a same or similar process flow. So, in an example, the dimensions of at least some of the interconnect structures 140a may be substantially similar to the dimensions of at least some of the interconnect structures 140b.

For example, as illustrated in FIG. 1G, at least part of an interconnect structure 140a and at least part of an interconnect structure 140b may be tapered, and an angle α1 by which the interconnect structures 140a, 140b are tapered may be substantially the same. FIG. 1G also illustrates a dimension L1 of the interconnect structures 140a, 140b, which may be the same for the interconnect structures 140a, 140b. FIG. 1G also illustrates another dimension L2, of the interconnect structures 140a, 140b, which may be the same for the interconnect structures 140a, 140b. Thus, the interconnect structure 140a and at least part of an interconnect structure 140b may have similar dimensions and/or similar tapering.

In some embodiments, the thermoelectric materials 108a, 108b, 110a, 110b are also be tapered. For example, sidewalls of individual ones of the thermoelectric materials 108a, 108b, 110a, 110b form an angle α2 with respect to a plane of the substrate. FIG. 1G also illustrates a dimension L3, which may be substantially same for the thermoelectric materials 108a, 108b, 110a, 110b. FIG. 1G also illustrates a dimension L4, which may be substantially same for the thermoelectric materials 108a, 108b, 110a, 110b. Thus, two or more of (e.g., each of) the thermoelectric materials 108a, 108b, 110a, 110b may have substantially same dimensions and/or substantially same tapering.

In some embodiments, for example where thermoelectric materials 108, 110 fill vias that have been opened using the same technique (e.g., laser drilling) as that employed to open vias for interconnect structures 140, the angle α2 may be substantially same as the angle α1. In some other examples however, the angle α2 may be different from the angle α1. In an example, the angle α2 may be less than 85 degrees, or less than 80 degrees.

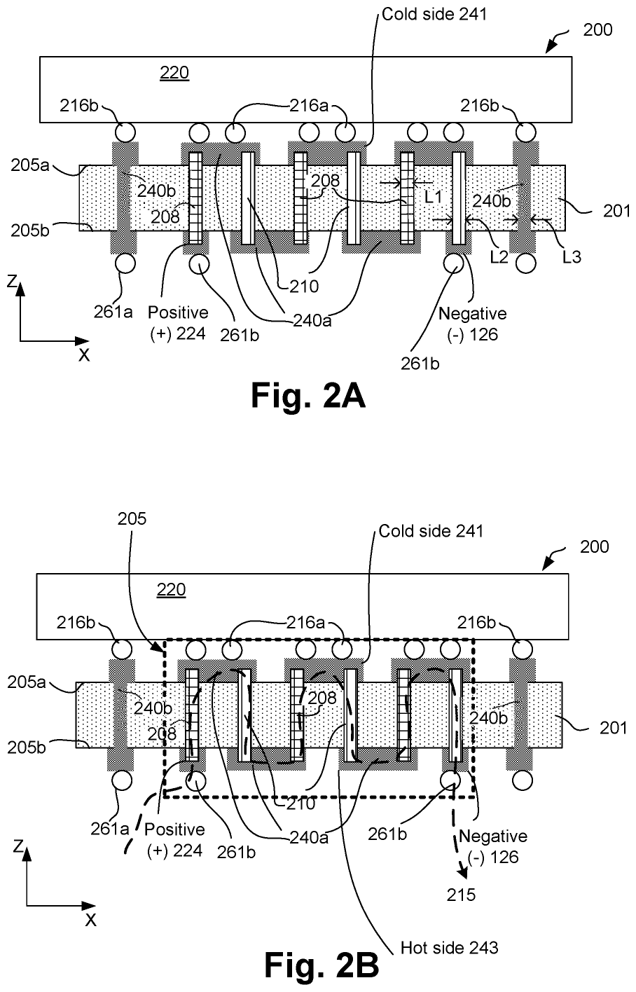

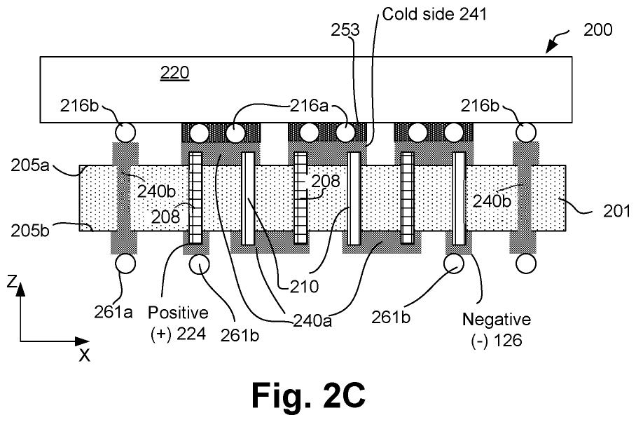

FIGS. 2A-2B schematically illustrate a cross-sectional view (e.g., along X-Z axis) of a semiconductor device package structure 200 (also referred to as package 200) that includes a thermoelectric cooling device 205 (also referred to as device 205) embedded at least in part within a substrate 201, e.g., to cool a component 220 coupled to the substrate 201, according to some embodiments. FIG. 2B illustrates a boundary (e.g., using dotted lines) of the device 205, and also illustrates a direction or path of flow of current 215 through the device 205, according to some embodiments. The device 205 includes thermoelectric materials 208, 210, e.g., at least in part similar to the thermoelectric materials 108, 110 of the package 100. However, as will be discussed in further details herein, a structure of the thermoelectric materials 208, 210 of the package 200 may be different from that of the thermoelectric materials 108, 110 of the package 100.

In an example, the component 220 may be similar to the component 120 of the package 100, and can be any electronic device or component that may be included in a semiconductor package, e.g., one or more IC dies, one or more chips, a processor, computer memory, platform controller hub, etc. In some embodiments, the substrate 201 includes one or more layers of dielectric material. In an example, the substrate 201 may include a core layer, e.g., a layer including core material. The substrate 201 may be at least in part similar to the substrate 101 of the package 100. The component 220 is attached to the substrate 201 in any suitable configuration, such as a flip-chip configuration.

The component 220 is coupled to the substrate 201 using a first plurality of interconnect structures 216a and a second plurality of interconnect structures 216b. In an example, a solder resist layer (e.g., similar to the solder resist layer 112 of the package 100) may at least in part encapsulate the interconnect structures 216, although such solder resist layer is not illustrated in FIGS. 2A-2B for purposes of illustrative clarity.

The interconnect structures 216 for example, are bumps, bump pads, metal pillars (e.g., copper pillars), balls formed using metals, alloys, solderable material, or the like. For example, the interconnect structures 216 are bumps, balls, and/or solder formed using metals, alloys, solderable material, and/or the like.

In some embodiments, the interconnect structures 216a are for thermally coupling the thermoelectric cooling device 205 (also referred to as device 205) to the component 220. For example, the interconnect structures 216a may not transmit electrical signals to, or from, the component 220, and merely provide a thermally conductive path between the component 220 and the device 205, e.g., similar to the interconnect structures 116a of the package 100.

In some embodiments, the interconnect structures 216b are for electrically coupling the component 220 to the substrate 201, e.g., similar to the interconnect structures 116b of the package 100. Although merely two electrical interconnect structures 216b are illustrated in FIG. 2A, the package 200 may comprise any appropriate number of such electrical interconnect structures.

The package 200 includes a plurality of interconnect structures 240a, and another plurality of interconnect structures 240b. The interconnect structures 240 are, for example, metallization levels, TSVs, conductive traces, routing structures, etc., embedded within various layers of the substrate 201. The interconnect structures 240 comprise metals, alloys, solderable material, or the like. In some embodiments, the substrate 201 includes an interconnect or metallization level (i.e., a routing layer) for trace routing and a dielectric layer for electrically insulating laterally adjacent traces as well as adjacent interconnect levels (overlying and/or underlying). The interconnect levels form the interconnect structures 240. Thus, the interconnect structures 240 may include conductive vias, TSVs, solder, traces, metallization levels, routing layers, etc.

In some embodiments, the interconnect structures 240a are included in the device 205, and are primarily (or exclusively) for transmitting current of the device 205, e.g., similar to the interconnect structures 140a of the package 100. In an example, the interconnect structures 240a are electrically isolated from the component 220.

In some embodiments, the interconnect structures 240b are electrically coupled to the component 220, e.g., similar to the interconnect structures 140b of the package 100. For example, the interconnect structures 240b transmit signals to, and from, the component 220. For example, the interconnect structures 240b are to communicate signals between the component 220 and a circuit board (not illustrated in FIG. 2A), where the package 200 may be coupled to the circuit board.

The package 200 includes the device 205. The device 205 includes thermoelectric materials 208, 210, similar to the thermoelectric materials 108, 110 of the package 100. For example, three sets of thermoelectric materials 208 and three sets of thermoelectric materials 210 are illustrated.

Merely as an example, the thermoelectric materials 208 are P-type thermoelectric materials, and the thermoelectric materials 210 are N-type thermoelectric materials (the location of P and N-type thermoelectric materials may be interchanged, for example, if a direction of current flow through the device 205 is reversed). The P-type and N-type thermoelectric materials are arranged in an interleaved manner, as illustrated in the figures. Any appropriate type of thermoelectric materials 208, 210 may be used, e.g., as discussed with respect to the package 100.

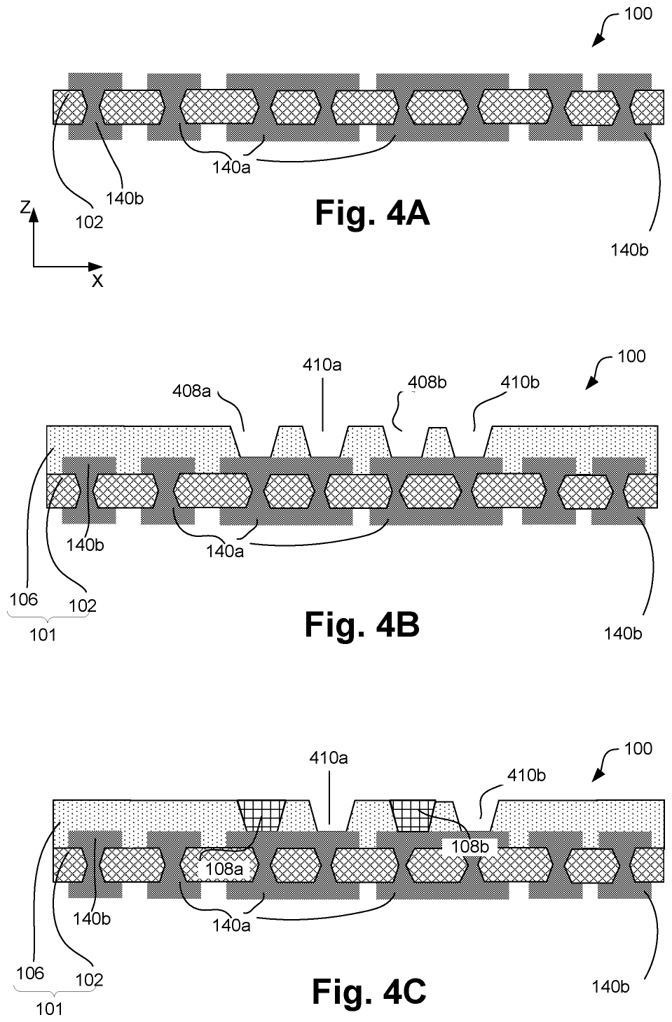

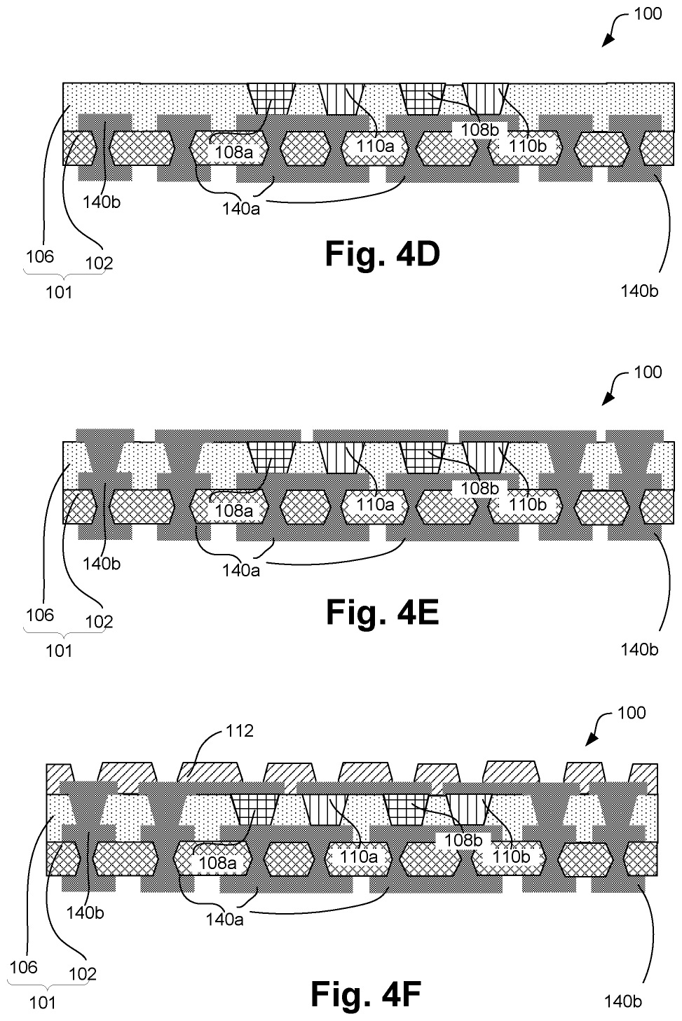

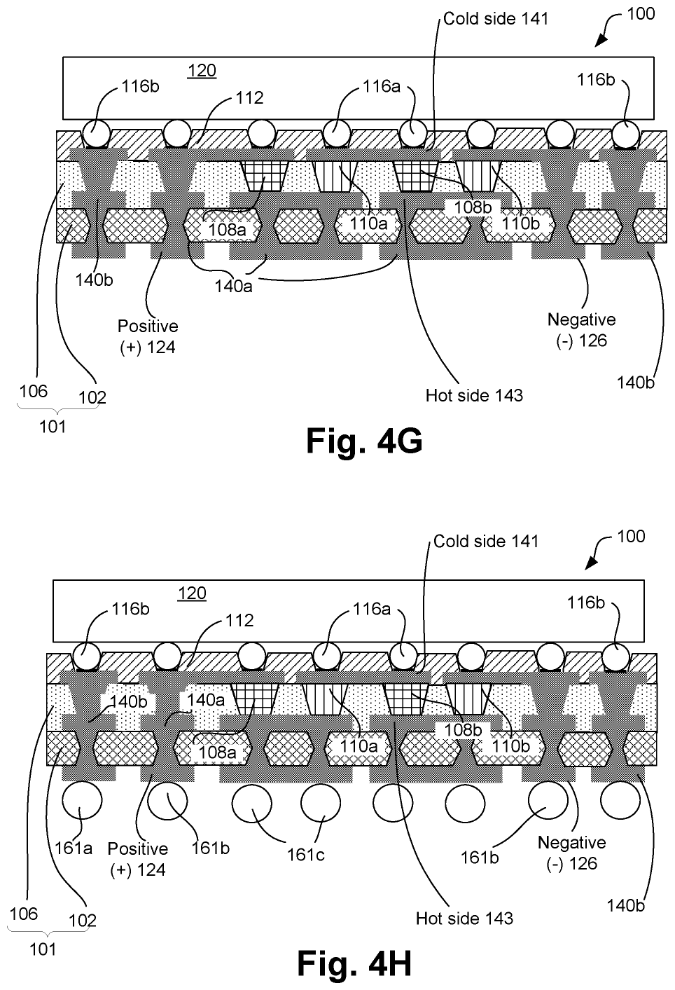

The thermoelectric materials 108, 110 of the package 100 are tapered, e.g., as discussed with respect to FIG. 1G. However, as illustrated in FIGS. 2A-2B, the thermoelectric materials 208, 210 of the package 200 are not tapered (e.g., not as tapered as the thermoelectric materials 108, 110 of the package 100). For example, as will be discussed herein later with respect to FIGS. 4B-4D, the thermoelectric materials 108, 110 of the package 100 are formed in laser-drilled cavities, which in some examples results in the tapered shapes of the thermoelectric materials 108, 110.

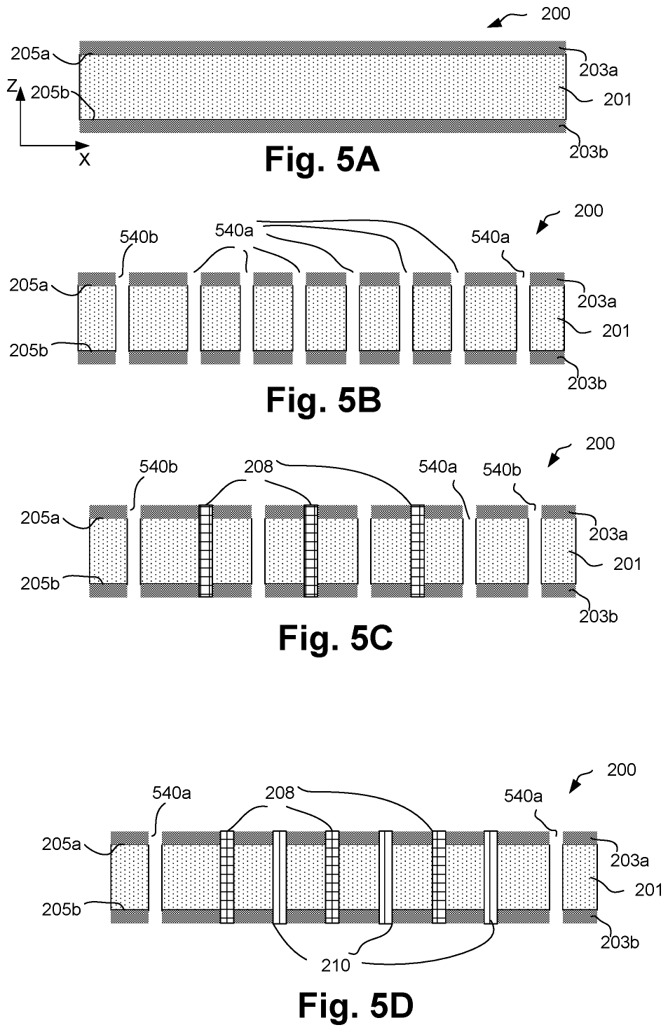

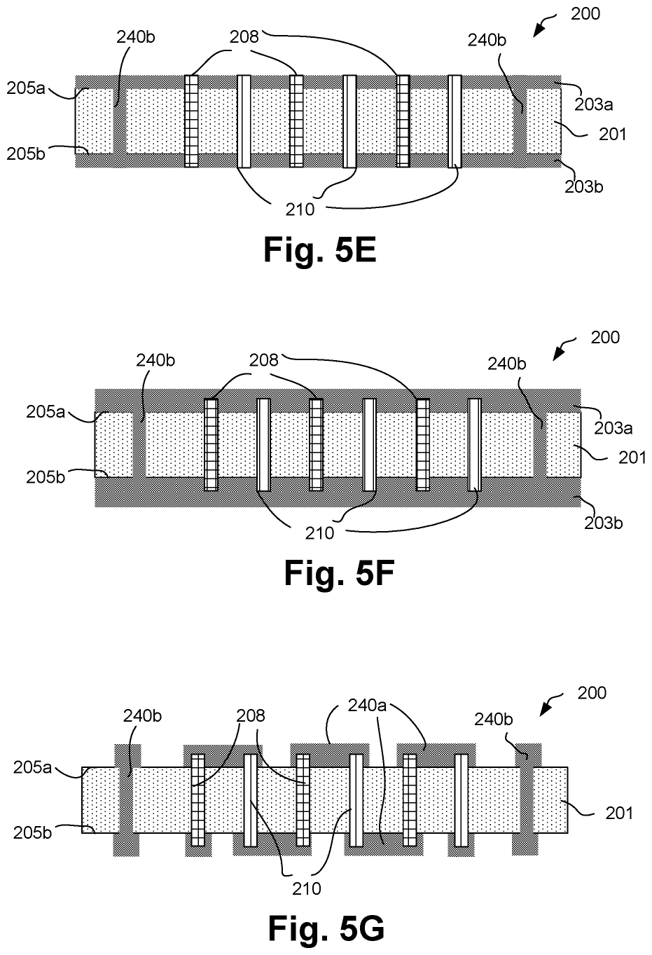

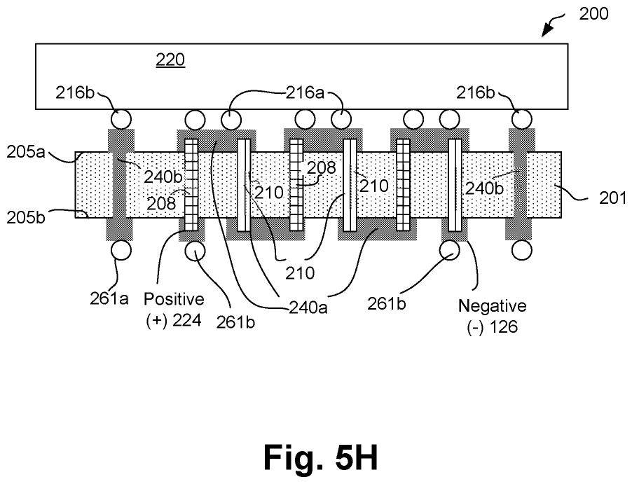

In contrast, as will be discussed herein later with respect to FIGS. 5B-5E, in some examples, the thermoelectric materials 208, 210 of the package 200 are formed in mechanical-drilled holes, which in some examples results in the relatively non-tapered shapes of the thermoelectric materials 208, 210. For example, sidewalls of the thermoelectric materials 208, 210 may be substantially vertical with respect to a surface of the substrate 201.

In some embodiments, cross-sectional dimensions (e.g., diameters) of the thermoelectric materials 208, 210 and the interconnect structures 240b may be substantially similar. For example, FIG. 2A illustrates the diameters of the thermoelectric materials 208, 210 and the interconnect structures 240b to be L1, L2, and L3, respectively. In an example L1, L2, and L3 are substantially same.

A positive terminal 224 and a negative terminal 226 of the device 205 is illustrated in FIGS. 2A-2B. FIG. 2B illustrates an example path of flow of the current 215 using a dotted line. For example, DC current flows through the device 205, from the positive terminal 224 to the negative terminal 226. The current 215 is transmitted from the positive terminal 224, through the interconnect structures 240a, the thermoelectric materials 208, 210, and exits the device 205 through the terminal 226, as illustrated in FIG. 2B.

The device 205 has a first side 241, and a second opposing side 243 (illustrated in FIG. 2B). In an example, due to the arrangement of the P-type thermoelectric material 208 and the N-type thermoelectric material 210 and the flow of current 215, the thermoelectric materials 208, 210 transfer heat from the side 241 to the side 243, e.g., due to the inherent properties of thermoelectric material (e.g., due to Peltier effect of thermoelectric material). Accordingly, the side 241 is also referred to herein as the cold side, and the side 243 is also referred to herein as the hot side.

As heat is transferred from the cold side 241 to the hot side 243 of the device 205, heat is removed from the component 220 (e.g., through the interconnect structures 216a) and released on the hot side 243. Thus, the device 205 transfers heat from the component 220, and aids in cooling of the component 220. For example, a bottom surface of the component 220 (e.g., a surface of the component 220 facing the substrate 201) may be cooled by the device 205.

Various variations of the package 200 may be possible. For example, FIG. 2C illustrates the package 200 of FIGS. 2A-2B, with a thermally conductive underfill material 253 between the component 220 and the device 205, according to some embodiments. The thermally conductive underfill material 253 may aid in transfer of heat from the component 220 to the cold side 241 of the device 205.

In an example and at least in part similar to FIG. 1E, the package 200 of FIGS. 2A-2B may be coupled to a circuit board (e.g., a PCB, a motherboard, etc.), although such a circuit board is not illustrated in FIGS. 2A-2B. For example, the package 200 may be coupled to the circuit board through interconnect structures 261 (e.g., similar to the interconnect structures 161 of FIG. 1E). In some embodiments, the interconnect structures 261 include interconnect structures 261a for electrically coupling the substrate 201 and the component 220 to the circuit board (e.g., similar to the interconnect structures 161a of FIG. 1E). In some embodiments, the interconnect structures 261 include interconnect structures 261b for electrically coupling the device 205 to the circuit board (e.g., similar to the interconnect structures 161b FIG. 1E). Furthermore, similar to the interconnect structures 161c of FIG. 1E, the package 200 may also include interconnect structures for thermally coupling the thermoelectric cooling device 205 to the circuit board, although such interconnect structures are not illustrated in FIGS. 2A-2B.

In an example and at least in part similar to FIG. 1F, the package 200 of FIGS. 2A-2B may include a heat spreader coupled to the hot side 243 of the device 205 (although such a heat spreader is not illustrated in FIGS. 2A-2B).

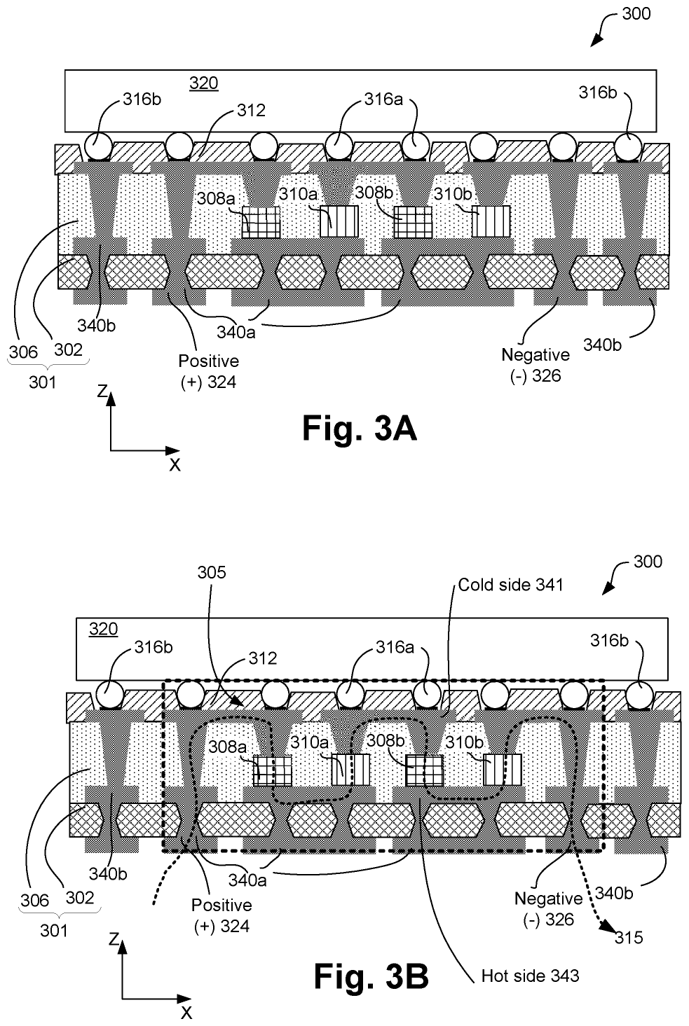

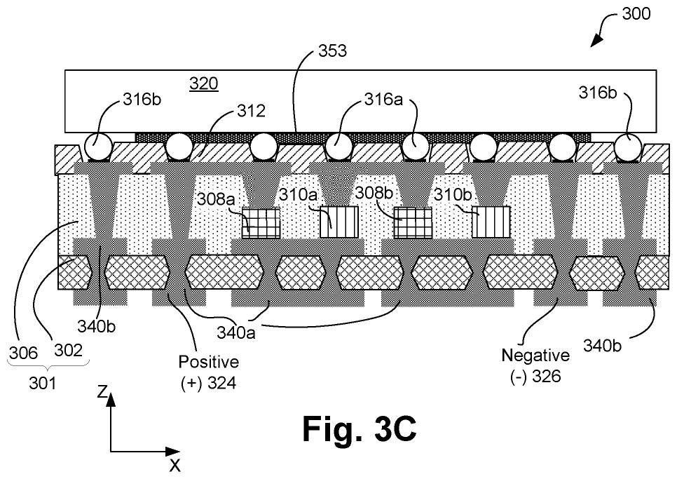

FIGS. 3A-3B schematically illustrate a cross-sectional view (e.g., along X-Z axis) of a semiconductor device package structure 300 (also referred to as package 300) that includes a thermoelectric cooling device 305 (where a boundary of the thermoelectric cooling device 305 is illustrated in FIG. 3B) embedded at least in part within a substrate 301, e.g., to cool a component 320 coupled to the substrate 301, according to some embodiments. FIG. 3B illustrates the boundary (e.g., using dotted lines) of the device 305, and also illustrates a direction or path of flow of current 315 through the device 305.

The thermoelectric materials 108, 110 of the package 100 are tapered, e.g., as discussed with respect to FIG. 1G. However, as illustrated in FIGS. 3A-3B, the thermoelectric materials 308, 310 of the package 300 are not tapered (e.g., not as tapered as the thermoelectric materials 308, 310 of the package 300).

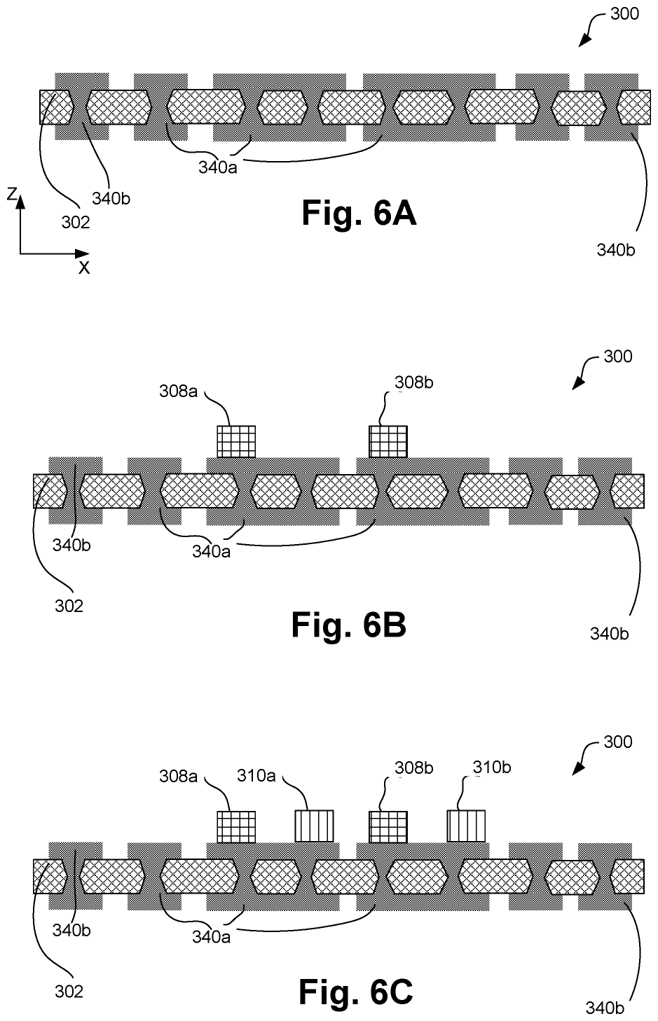

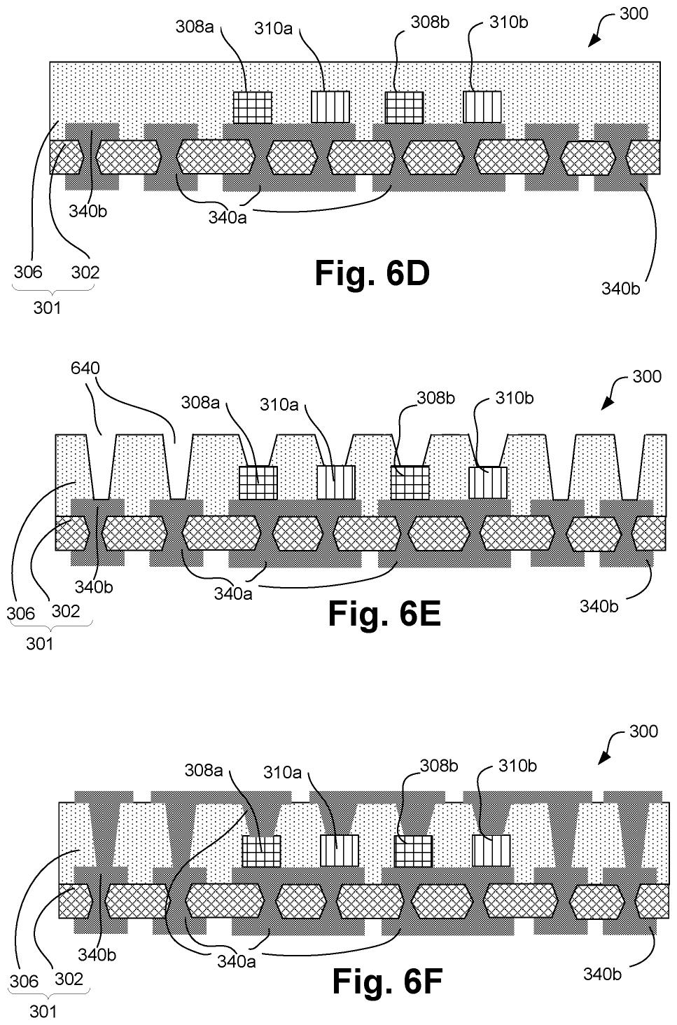

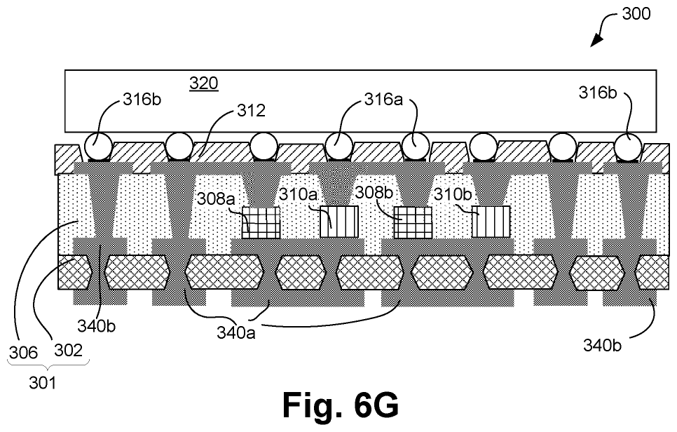

For example, as will be discussed herein later with respect to FIGS. 4B-4D, the thermoelectric materials 108, 110 of the package 100 are formed in laser-drilled cavities, which in some examples results in the tapered shapes of the thermoelectric materials 108, 110. In contrast, as will be discussed herein later with respect to FIGS. 6B-6C, in some examples, the thermoelectric materials 308, 310 of the package 300 are formed by sputtering, by physical vapor deposition (PVD) method of thin film deposition, by electroplating, etc., and hence, may not be tapered. For example, sidewalls of the thermoelectric materials 308, 310 may be substantially vertical, e.g., substantially at 90 degree angle with respect to a plane of the substrate 301.

The component 320 may be similar to the component 120 of the package 100, in an example, and can be any electronic device or component that may be included in a semiconductor package, e.g., one or more IC dies, one or more chips, a processor, computer memory, platform controller hub, etc. In some embodiments, the substrate 301 includes a layer 302 of core material and one or more layers 306 of dielectric material. The substrate 301 may be at least in part similar to the substrate 301 of the package 100.

The component 320 is attached to the substrate 301 in any suitable configuration, such as a flip-chip configuration. The component 320 is coupled to the substrate 301 using a first plurality of interconnect structures 316a and a second plurality of interconnect structures 316b. In an example, a solder resist layer 312 (e.g., similar to the solder resist layer 112 of the package 100) at least in part encapsulates the interconnect structures 316.

The interconnect structures 316 for example, are bumps, bump pads, metal pillars (e.g., copper pillars), balls formed using metals, alloys, solderable material, or the like. For example, the interconnect structures 316 are bumps, balls, and/or solder formed using metals, alloys, solderable material, and/or the like.

In some embodiments, the interconnect structures 316a are for thermally coupling the thermoelectric cooling device 305 (also referred to as device 305) to the component 320. For example, the interconnect structures 316a may not transmit electrical signals to, or from, the component 320, and merely provide a thermally conductive path between the component 320 and the device 305, e.g., similar to the interconnect structures 116a of the package 100.

In some embodiments, the interconnect structures 316b are for electrically coupling the component 320 to the substrate 301, e.g., similar to the interconnect structures 116b of the package 100. Although merely two electrical interconnect structures 316b are illustrated in FIG. 3A, the package 300 may comprise any appropriate number of such electrical interconnect structures.

The package 300 includes a plurality of interconnect structures 340a, and another plurality of interconnect structures 340b. The interconnect structures 340 are, for example, metallization levels, through silicon vias (TSVs), conductive traces, routing structures, etc., embedded within various layers of the substrate 301. The interconnect structures 340 comprise metals, alloys, solderable material, or the like. In some embodiments, the substrate 301 includes an interconnect or metallization level (i.e., a routing layer) for trace routing and a dielectric layer for electrically insulating laterally adjacent traces as well as adjacent interconnect levels (overlying and/or underlying). The interconnect levels form the interconnect structures 340. Thus, the interconnect structures 340 may include conductive vias, TSVs, solder, traces, metallization levels, routing layers, etc.

In some embodiments, the interconnect structures 340a are included in the device 305, and are primarily (or exclusively) for transmitting current of the device 305, e.g., similar to the interconnect structures 140a of the package 100. In an example, the interconnect structures 340a are electrically isolated from the component 320.

In some embodiments, the interconnect structures 340b are electrically coupled to the component 320, e.g., similar to the interconnect structures 140b of the package 100. For example, the interconnect structures 340b transmit signals to, and from, the component 320. For example, the interconnect structures 340b are to communicate signals between the component 320 and a circuit board (not illustrated in FIG. 3A), where the package 300 may be coupled to the circuit board.

In some embodiments, the device 305 includes thermoelectric materials 308a, 308b, 310a, 310b, e.g., similar to the thermoelectric materials 108, 110 of the package 100. Merely as an example, the thermoelectric materials 308a, 308b are P-type thermoelectric materials, and the thermoelectric materials 310a, 310b are N-type thermoelectric materials. The P-type and N-type thermoelectric materials are arranged in an interleaved manner, as illustrated in the figures. Any appropriate type of thermoelectric materials 308, 310 may be used, e.g., as discussed with respect to the package 300. Although two sets of P-type thermoelectric materials 308 and two sets of N-type thermoelectric materials 310 are illustrated, the device 300 may include any other appropriate number of P and N-type thermoelectric materials.

A positive terminal 324 and a negative terminal 326 of the device 305 is illustrated in FIGS. 3A-3B. FIG. 3B illustrates an example path of flow of the current 315 using a dotted line. For example, DC current flows through the device 305, from the positive terminal 324 to the negative terminal 326. The current 315 is transmitted from the positive terminal 324, through the interconnect structures 340a, the thermoelectric materials 308, 310, and exits the device 305 through the terminal 326, as illustrated in FIG. 3B.

The device 305 has a first side 341, and a second opposing side 343 (illustrated in FIG. 3B). In an example, due to the arrangement of the P-type thermoelectric material 308 and the N-type thermoelectric material 310 and the flow of current 315, the thermoelectric materials 308, 310 transfer heat from the side 341 to the side 343, e.g., due to the inherent properties of the thermoelectric material (e.g., due to Peltier effect of thermoelectric material). Accordingly, the side 341 is also referred to herein as the cold side, and the side 343 is also referred to herein as the hot side.

As heat is transferred from the cold side 341 to the hot side 343 of the device 305, heat is removed from the component 320 (e.g., through the interconnect structures 316a) and released on the hot side 343. Thus, the device 305 transfers heat from the component 320, and aids in cooling of the component 320. For example, a bottom surface of the component 320 (e.g., a surface of the component 320 facing the substrate 301) may be cooled by the device 305.

Various variations of the package 300 may be possible. For example, FIG. 3C illustrates the package 300 of FIGS. 3A-3B, with a thermally conductive underfill material 353 between the component 320 and the device 305, according to some embodiments. The thermally conductive underfill material 353 may aid in transfer of heat from the component 320 to the cold side 341 of the device 305.

In an example and at least in part similar to FIG. 1E, the package 300 of FIGS. 3A-3B may be coupled to a circuit board (e.g., a PCB, a motherboard, etc.), although such a circuit board is not illustrated in FIGS. 3A-3B. For example, the package 300 may be coupled to the circuit board through a plurality of interconnect structures (e.g., not illustrated in FIGS. 3A-3B, and similar to the interconnect structures 161 of FIG. 1E).

In an example and at least in part similar to FIG. 1F, the package 300 of FIGS. 3A-3B may include a heat spreader coupled to the hot side 343 of the device 305 (although such a heat spreader is not illustrated in FIGS. 3A-3B).

FIGS. 4A, 4B, 4C, 4D, 4E, 4F, 4G, and 4H illustrate example processes for formation of the semiconductor device package structure 100 (e.g., package 100) of any of FIGS. 1A-1G, according to some embodiments. For example, FIGS. 4A-4H are cross-sectional views of the package 100 evolving as example operations for formation of the package 100 are performed.

Referring to FIG. 4A, the core layer 102 of the substrate 101 is provided. The core layer 102 includes metallization levels embedded within the core layer 102, where the metallization levels are labelled as 140a, 140b, e.g., as the metallization levels 140 are part of the interconnect structures 140 of the package 100. The metallization levels 140 includes, for example, metal, such as copper.

Referring now to FIG. 4B, substrate layer 106 is formed (e.g., deposited or laminated) over the core layer 102. Cavities 408a, 408b, 410a, 410b are formed within the substrate layer 106. The cavities 408a, 408b, 410a, 410b may be formed using any appropriate technique for forming cavities in a substrate, such as laser drilling, mechanical drilling, etc. In an example, laser drilling is used to form the cavities, and as a result, the cavities may be tapered.

Referring now to FIG. 4C, cavities 408a, 408b are filled with P-type thermoelectric materials 108a, 108b, respectively. For example, P-type thermoelectric material paste may be printed in the cavities 408a, 408b.

Referring now to FIG. 4D, cavities 410a, 410b are filled with N-type thermoelectric materials 110a, 110b, respectively. For example, N-type thermoelectric material paste may be printed in the cavities 410a, 410b.

After the operations of each of FIG. 4C and 4D, or after operations of FIG. 4D, the thermoelectric materials 108, 110 may be cured and grinded. In an example, an order of the operations at FIGS. 4C and 4D may be interchanged (e.g., operations of FIG. 4D may be executed prior to the operations of FIG. 4C).

Referring now to FIG. 4E, interconnect structures 140a, 140b may be completed within the substrate layer 106. Any appropriate techniques for forming the interconnect structures 140a, 140b embedded within the substrate layer 106 may be used.

Referring now to FIG. 4F, solder resist layer 112 may be laminated over the substrate 106, and patterned to form openings. Referring now to FIG. 4G, interconnect structures 116a, 116b are formed in the openings of the solder resist layer 112. The component 120 is coupled to the substrate 101 through the interconnect structures 116a, 116b. The package 100 of FIG. 4G is similar to the package 100 of FIGS. 1A-1C.

Referring now to FIG. 4H, interconnect structures 161a, 161b, 161c are coupled to the substrate 101. The package 100 of FIG. 4H is similar to the package 100 of FIG. 1E (although the circuit board 160 of FIG. 1E is not illustrated in FIG. 4H).

FIGS. 5A, 5B, 5C, 5D, 5E, 5F, 5G, and 5H illustrate example processes for formation of the semiconductor device package structure 200 (e.g., package 200) of FIGS. 2A-2B, according to some embodiments. For example, FIGS. 5A-5H are cross-sectional views of the package 200 evolving as example operations for formation of the package 200 are performed.

Referring to FIG. 5A, the substrate 201 is provided. The substrate 201 has a layer 203a on a first side 205a of the substrate 201, and has a layer 203b on a second side 205b of the substrate 201. The layers 203a, 203b includes electrically conductive material, such as metal (e.g., copper).

Referring now to FIG. 5B, through holes 540a, 540b are formed on the package 200. The through holes 540 may be formed using a mechanical drill, a laser drill, etc., followed by desmear process. As discussed herein later in further details, the holes 540b may be for forming the interconnect structures 240b that are electrically coupled to the component 220, and the holes 540a may be for depositing the thermoelectric materials 208, 210. Because the holes 540a, 540b are formed using the same or similar hole formation process (e.g., mechanical drilling, or laser drilling), in an example, dimensions (e.g., widths) of the holes 540a, 540b may be substantially similar in the package 200. Accordingly, dimensions (e.g., widths) of the interconnect structures 240b and individual ones of the thermoelectric materials 208, 210 may be substantially similar.

Referring now to FIG. 5C, some of the holes 540a (e.g., alternate holes) are filled with P-type thermoelectric materials 208. For example, P-type thermoelectric material paste may be plugged in alternate ones of the holes 540a.

Referring now to FIG. 5D, remaining of the holes 540a are filled with N-type thermoelectric materials 210. For example, N-type thermoelectric material paste may be plugged in the remaining holes 540a.

After the operations of each of FIG. 5C and 5D, or after operations of FIG. 5D, the thermoelectric material 208, 210 may be cured and grinded. In an example, an order of the operations at FIGS. 5C and 5D may be interchanged (e.g., operations of FIG. 5D may be executed prior to the operations of FIG. 5C).

Referring now to FIG. 5E, interconnect structures 240b may be formed within the holes 540a (the holes 540a are illustrated in FIG. 5D, and not illustrated in FIG. 5E). Any appropriate techniques for forming the interconnect structures 240b embedded within the substrate layer 1106 may be used. The interconnect structures 240b may be through silicon vias (TSV). The formation of interconnect structures 240b may involve one or more of plating the walls of the holes 540b using electroless metal deposition, plugging the holes 540b with conductive material (e.g., copper), curing, grinding, etc.

Referring now to FIG. 5F, the layers 203a, 203b may be extended, e.g., to cover the exposed ends of the thermoelectric materials 208, 210, using any appropriate techniques, e.g., metal plating, grinding, demear, etc.

Referring now to FIG. 5G, the layers 203a, 203b may be patterned and subtractively etched, to form interconnect structures 240a, 240b. Referring to FIG. 5H, interconnect structures 216a, 216b, 261a, 261b may be coupled to the substrate 101 (e.g., coupled to the corresponding ones of the interconnect structures 240a, 240b), e.g., through appropriate solder resist layer (where the solder resist layer is not illustrated in FIG. 5H). The package 200 of FIG. 5H is similar to the package 200 of FIG. 2A.

FIGS. 6A, 6B, 6C, 6D, 6E, 6F, and 6G illustrate example processes for formation of the semiconductor device package structure 300 (e.g., package 300) of FIGS. 3A-3B, according to some embodiments. For example, FIGS. 6A-6G are cross-sectional views of the package 300 evolving as example operations for formation of the package 300 are performed.

Referring to FIG. 6A, the core layer 302 of the substrate 301 is provided. The core layer 302 includes metallization levels embedded within the core layer 302, where the metallization levels are labelled as 340a, 340b, e.g., as the metallization levels 340 are part of the interconnect structures 340 of the package 300. The metallization levels 340 includes, for example, metal, such as copper.

Referring now to FIG. 6B, P-type thermoelectric materials 308a, 308b are formed. In some embodiments, the thermoelectric materials 308a, 308b are deposited by sputtering, by physical vapor deposition (PVD) method of thin film deposition, etc.

In some other embodiments, the P-type thermoelectric materials 308a, 308b are deposited using electroplating. For example, patterned dry film resist layer (not illustrated in the figures) may be formed on the package, and the P-type thermoelectric materials 308a, 308b are electroplated through openings in the patterned dry film resist layer.

Referring now to FIG. 6C, N-type thermoelectric material 310a, 310b are formed, e.g., similar to the formation of the thermoelectric material 308. In an example, an order of the operations at FIGS. 6B and 6C may be interchanged (e.g., operations of FIG. 6C may be executed prior to the operations of FIG. 6B).

Referring now to FIG. 6D, substrate layers 306 may be formed (e.g., laminated over the core layer 302). Referring now to FIG. 6E, vias or openings 640 are formed in the substrate 306, e.g., using mechanical drilling, laser drilling, or any other appropriate technique. Referring now to FIG. 6F, interconnect structures 340a, 340b are completed within the substrate layer 306. Any appropriate techniques for forming the interconnect structures 340a, 340b embedded within the substrate layer 306 may be used.

Referring now to FIG. 6G, solder resist layer 312 is laminated over the substrate 106, and patterned to form openings. Interconnect structures 316a, 316b are formed in the openings of the solder resist layer 312. The component 320 is coupled to the substrate 301 through the interconnect structures 316a, 316b. The package 300 of FIG. 6G is similar to the package 300 of FIGS. 3A-3B.

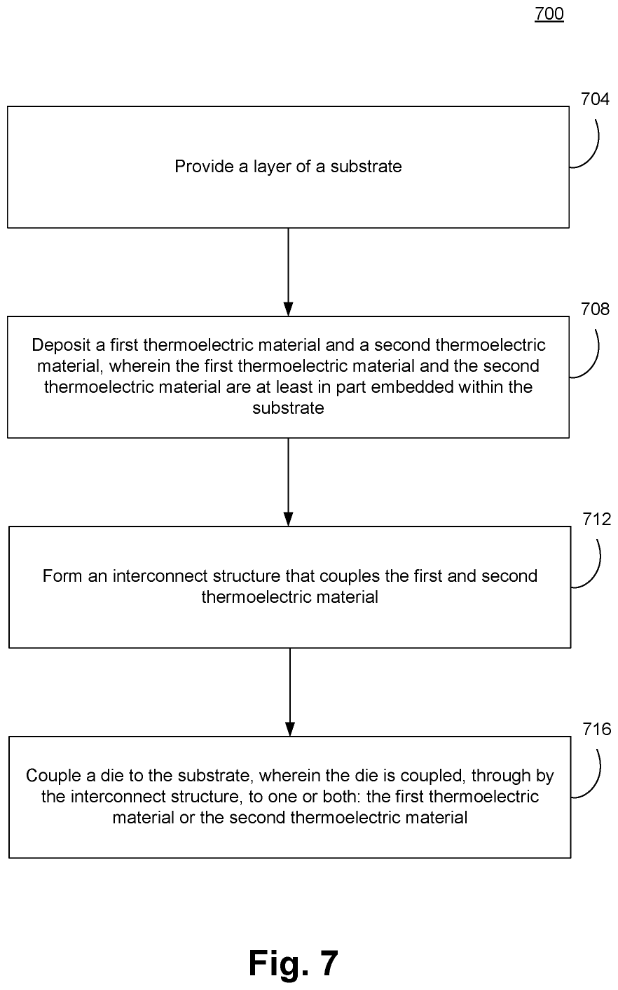

FIG. 7 illustrates a flowchart depicting a method 700 for forming a semiconductor device package structure (e.g., any of the packages 100, 200, or 300 of FIGS. 1A-3B) that includes a thermoelectric cooling device embedded at least in part within a substrate, e.g., to cool a component coupled to the substrate, according to some embodiments. Although the blocks in the flowchart with reference to FIG. 7 are shown in a particular order, the order of the actions can be modified. Thus, the illustrated embodiments can be performed in a different order, and some actions/blocks may be performed in parallel. Some of the blocks and/or operations listed in FIG. 7 may be optional in accordance with certain embodiments. The numbering of the blocks presented is for the sake of clarity and is not intended to prescribe an order of operations in which the various blocks must occur.

The method 700 includes, at 704, providing a layer of a substrate (e.g., any of the substrate 101, 201, or 301, e.g., as discussed with respect to FIGS. 4A, 4B, 5A, 6A, etc.). In an example, the layer includes dielectric material.

At 708, a first thermoelectric material and a second thermoelectric material (e.g., any of the thermoelectric materials 108, 110, thermoelectric materials 208, 210, thermoelectric materials 308, 310, or the like) are deposited. For example, the first thermoelectric material and the second thermoelectric material are at least in part embedded within the substrate.

In some embodiments, depositing the first thermoelectric material and the second thermoelectric material includes: forming a first recess and a second recess in the layer of substrate; depositing the first thermoelectric material in the first recess; and depositing the second thermoelectric material in the second recess, e.g., as discussed with respect to FIG. 4B-4D, or as discussed with respect to FIGS. 5B-5D.

In some embodiments, depositing the first thermoelectric material and the second thermoelectric material includes: forming a patterned dry film resist layer on the substrate; depositing the first thermoelectric material through a first opening in the dry film resist layer, and the second thermoelectric material through a second opening in the film resist layer; and removing the dry film resist layer, as discussed with respect to FIG. 6B-6C.

At 712, an interconnect structure (e.g., any of the interconnect structure 140a, 240b, 340a, or the like) is formed, where the interconnect structure couples the first and second thermoelectric material.

At 716, a die (e.g., any to the components 120, 220, 320, or the like) is coupled to the substrate. The die may be coupled, through the interconnect structure, to one or both: the first thermoelectric material or the second thermoelectric material.

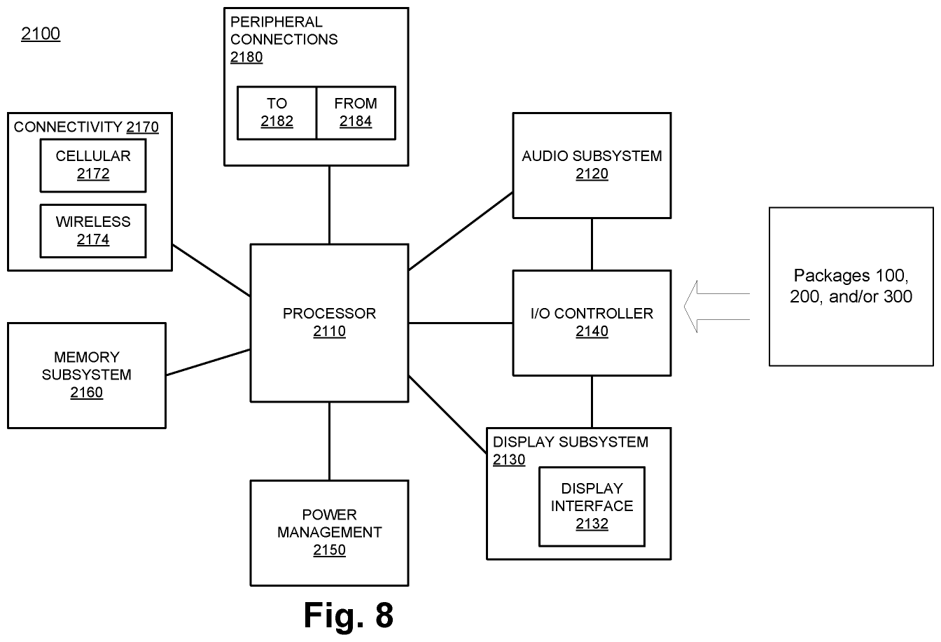

FIG. 8 illustrates a computer system, a computing device or a SoC (System-on-Chip) 2100, where one or more components of the computing device 2100 are included in a semiconductor package (e.g., any of the semiconductor packages discussed herein, such as packages 100, 200, or 300) that includes a thermoelectric cooling device embedded at least in part within a substrate, e.g., to cool a component coupled to the substrate, according to some embodiments. It is pointed out that those elements of FIG. 8 having the same reference numbers (or names) as the elements of any other figure can operate or function in any manner similar to that described, but are not limited to such.

In some embodiments, computing device 2100 represents an appropriate computing device, such as a computing tablet, a mobile phone or smart-phone, a laptop, a desktop, an TOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O with a human user or with other devices, operations related to power management, and/or operations related to connecting the computing device 2100 to another device. The I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100. In one embodiment, computing device 2100 includes a clock generation subsystem to generate a clock signal.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, one or more components of the computing device 2100 may be included in one or more IC dies (e.g., components 120, 220, 320 0discussed with respect to FIGS. 1-7). For example, the processor 2110 and/or a memory of the memory subsystem 2160 is included in any of the components 120, 220, 320. The components 120, 220, 320 are included in a semiconductor device package (e.g., any of packages 100, 200, 300 of FIGS. 1-7) of the computing device 2100. Thus, one or more of the packages 100, 200, and/or 300 may be included in the computing device 2100. The packages may include a thermoelectric cooling device embedded at least in part within a substrate, e.g., to cool the component coupled to the substrate, as discussed herein with respect to FIGS. 1-7.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

Example 1. A semiconductor device package structure comprising: a substrate; a die coupled to the substrate; and a thermoelectric device comprising a P-type semiconductor material, a N-type semiconductor material, and a plurality of interconnect structures to transmit current through the P-type and N-type semiconductor material, wherein the P-type semiconductor material and the N-type semiconductor material are at least in part embedded within the substrate, wherein the thermoelectric device has a first side proximal to the die, and a second side separated from the die by the first side.

Example 2. The semiconductor device package structure of example 1 or any other example, wherein: the plurality of interconnect structures is a first plurality of interconnect structures; and the semiconductor device package structure comprises a second plurality of interconnect structures to electrically couple the substrate to the die, wherein the second plurality of interconnect structures is electrically isolated from the first plurality of interconnect structures.

Example 3. The semiconductor device package structure of example 2 or any other example, wherein: the first plurality of interconnect structures includes a first interconnect structure; the second plurality of interconnect structures includes a second interconnect structure; the first interconnect structure and the second interconnect structure are at a same level within the substrate; and an angle of a sidewall of the first interconnect structure with respect to a surface of the substrate is substantially same as an angle of a sidewall of the second interconnect structure with respect to the surface of the substrate.

Example 4. The semiconductor device package structure of example 1 or any other example, wherein the plurality of interconnect structures comprises: a first interconnect structure to transmit current to the N-type semiconductor material; a second interconnect structure to transmit current from the N-type semiconductor material to the P-type semiconductor material; and a third interconnect structure to transmit current from the P-type semiconductor material.

Example 5. The semiconductor device package structure of example 4 or any other example, wherein one or both the P-type semiconductor material or the N-type semiconductor material are coupled to the die through the second interconnect structure.

Example 6. The semiconductor device package structure of example 4 or any other example, wherein the second interconnect structure is coupled to the die by first one or more interconnect structures, wherein the plurality of interconnect structures excludes the first one or more interconnect structures.

Example 7. The semiconductor device package structure of example 4 or any other example, further comprising: thermally conductive underfill material between the die and the second interconnect structure.

Example 8. The semiconductor device package structure of example 1 or any other example, wherein at least one of the P-type semiconductor material or the N-type semiconductor material extends from a first surface of the substrate to an opposing second surface of the substrate.

Example 9. The semiconductor device package structure of example 1 or any other example, wherein the P-type semiconductor material is a first thermoelectric material, the N-type semiconductor material is a second thermoelectric material, and wherein the semiconductor device package structure comprises: a third thermoelectric material and a fourth thermoelectric material embedded within the substrate, wherein the third, first second, and fourth thermoelectric material are electrically coupled in series, wherein two of the first, second, third, and fourth thermoelectric material are P-type thermoelectric material, wherein another two of the first, second, third, and fourth thermoelectric material are N-type thermoelectric material, and wherein the first, second, third, and fourth thermoelectric material are arranged to have interleaved P-type and N-type thermoelectric materials.

Example 10. The semiconductor device package structure of example 1 or any other example, wherein at least one of the N-type semiconductor material or the P-type semiconductor material has a figure of merit higher than 0.3.

Example 11. The semiconductor device package structure of example 1 or any other example, wherein one or both the N-type semiconductor material or the P-type semiconductor material comprises at least one of: Tellurium (TE), or Bismuth (Bi).

Example 12. The semiconductor device package structure of example 1 or any other example, wherein one or both the N-type semiconductor material or the P-type semiconductor material comprise at least one of: Bulk Bismuth Telluride Pellets, Bismuth Telluride Ink, Selanylidene (Tellanylidene) Bismuth paint, Bismuth Telluride particle, or electroplated bismuth Telluride thin film.

Example 13. The semiconductor device package structure of example 1 or any other example, wherein the plurality of interconnect structures are inoperable to transmit current to or from the die.

Example 14. The semiconductor device package structure of example 1 or any other example, wherein individual ones of the P-type semiconductor material or the N-type semiconductor material is thermoelectric material, which is to transfer heat in response to current flowing through the semiconductor material.

Example 15. The semiconductor device package structure of example 1 or any other example, wherein: a sidewall of the P-type semiconductor material is at a first angle with respect to a surface of the substrate; a sidewall of the N-type semiconductor material is at a second angle with respect to a surface of the substrate; the first angle is substantially same as the second angle; and each of the first angle and the second angle is less than 85 degrees.

Example 16. The semiconductor device package structure of example 1 or any other example, wherein: a sidewall of the P-type semiconductor material is substantially vertical with respect to a surface of the substrate; and a sidewall of the N-type semiconductor material is substantially vertical with respect to the surface of the substrate.

Example 17. A system comprising: a circuit board; a die; a substrate having a first surface coupled to the circuit board and an opposing second surface coupled to the die; a thermoelectric device comprising a P-type semiconductor material, a N-type semiconductor material, and a plurality of interconnect structures to transmit current from the circuit board and through the P-type and N-type semiconductor materials, wherein the P-type semiconductor material and the N-type semiconductor material are at least in part embedded within the substrate, and wherein the thermoelectric device has a first side proximal to the die, and a second side separated from the die by the first side.

Example 18. The system of example 17 or any other example, further comprising: a power supply system to supply power to the thermoelectric device; and a wireless interface to facilitate communication between the system and another system, wherein the die includes at least one of: a memory to store instructions, or a processor to execute the instructions, wherein one or both the P-type semiconductor material or the N-type semiconductor material comprises at least one of: Tellurium (TE), or Bismuth (Bi), and wherein the plurality of interconnect structures are inoperable to transmit current to or from the die.

Example 19. A method comprising: providing a layer of a substrate, the layer comprising dielectric material; depositing a first thermoelectric material and a second thermoelectric material, wherein the first thermoelectric material and the second thermoelectric material are at least in part embedded within the substrate; forming an interconnect structure that couples the first and second thermoelectric material; and coupling a die to the substrate, wherein the die is coupled, through by the interconnect structure, to one or both: the first thermoelectric material or the second thermoelectric material.

Example 20. The method of example 19 or any other example, wherein depositing the first thermoelectric material and the second thermoelectric material comprises: forming a first recess and a second recess in the layer of substrate; depositing the first thermoelectric material in the first recess; and depositing the second thermoelectric material in the second recess.

Example 21. The method of example 19 or any other example, wherein depositing the first thermoelectric material and the second thermoelectric material comprises: forming a patterned dry film resist layer on the substrate; depositing the first thermoelectric material through a first opening in the dry film resist layer, and the second thermoelectric material through a second opening in the film resist layer; and removing the dry film resist layer.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. A semiconductor device package structure comprising:
a substrate;
a die coupled to the substrate; and
a thermoelectric device comprising a P-type semiconductor material, a N-type semiconductor material, and a plurality of interconnect structures to transmit current through the P-type and N-type semiconductor material,
wherein the P-type semiconductor material and the N-type semiconductor material are at least in part embedded within the substrate,
wherein the thermoelectric device has a first side proximal to the die, and a second side separated from the die by the first side.

2. The semiconductor device package structure of claim 1, wherein:
the plurality of interconnect structures is a first plurality of interconnect structures; and
the semiconductor device package structure comprises a second plurality of interconnect structures to electrically couple the substrate to the die,
wherein the second plurality of interconnect structures is electrically isolated from the first plurality of interconnect structures.

3. The semiconductor device package structure of claim 2, wherein:
the first plurality of interconnect structures includes a first interconnect structure;
the second plurality of interconnect structures includes a second interconnect structure;
the first interconnect structure and the second interconnect structure are at a same level within the substrate; and
an angle of a sidewall of the first interconnect structure with respect to a surface of the substrate is substantially same as an angle of a sidewall of the second interconnect structure with respect to the surface of the substrate.

4. The semiconductor device package structure of claim 1, wherein the plurality of interconnect structures comprises:
a first interconnect structure to transmit current to the N-type semiconductor material;
a second interconnect structure to transmit current from the N-type semiconductor material to the P-type semiconductor material; and
a third interconnect structure to transmit current from the P-type semiconductor material.

5. The semiconductor device package structure of claim 4, wherein one or both the P-type semiconductor material or the N-type semiconductor material are coupled to the die through the second interconnect structure.

6. The semiconductor device package structure of claim 4, wherein the second interconnect structure is coupled to the die by first one or more interconnect structures, wherein the plurality of interconnect structures excludes the first one or more interconnect structures.

7. The semiconductor device package structure of claim 4, further comprising:
thermally conductive underfill material between the die and the second interconnect structure.

8. The semiconductor device package structure of claim 1, wherein at least one of the P-type semiconductor material or the N-type semiconductor material extends from a first surface of the substrate to an opposing second surface of the substrate.

9. The semiconductor device package structure of claim 1, wherein the P-type semiconductor material is a first thermoelectric material, the N-type semiconductor material is a second thermoelectric material, and wherein the semiconductor device package structure comprises:
a third thermoelectric material and a fourth thermoelectric material embedded within the substrate,
wherein the third, first second, and fourth thermoelectric material are electrically coupled in series,
wherein two of the first, second, third, and fourth thermoelectric material are P-type thermoelectric material,
wherein another two of the first, second, third, and fourth thermoelectric material are N-type thermoelectric material, and
wherein the first, second, third, and fourth thermoelectric material are arranged to have interleaved P-type and N-type thermoelectric materials.

10. The semiconductor device package structure of claim 1, wherein at least one of the N-type semiconductor material or the P-type semiconductor material has a figure of merit higher than 0.3.

11. The semiconductor device package structure of claim 1, wherein one or both the N-type semiconductor material or the P-type semiconductor material comprises at least one of: Tellurium (TE), or Bismuth (Bi).

12. The semiconductor device package structure of claim 1, wherein one or both the N-type semiconductor material or the P-type semiconductor material comprise at least one of: Bulk Bismuth Telluride Pellets, Bismuth Telluride Ink, Selanylidene (Tellanylidene) Bismuth paint, Bismuth Telluride particle, or electroplated bismuth Telluride thin film.

13. The semiconductor device package structure of claim 1, wherein the plurality of interconnect structures are inoperable to transmit current to or from the die.

14. The semiconductor device package structure of claim 1, wherein individual ones of the P-type semiconductor material or the N-type semiconductor material is thermoelectric material, which is to transfer heat in response to current flowing through the semiconductor material.

15. The semiconductor device package structure of claim 1, wherein:
a sidewall of the P-type semiconductor material is at a first angle with respect to a surface of the substrate;
a sidewall of the N-type semiconductor material is at a second angle with respect to a surface of the substrate;
the first angle is substantially same as the second angle; and
each of the first angle and the second angle is less than 85 degrees.

16. The semiconductor device package structure of claim 1, wherein:
a sidewall of the P-type semiconductor material is substantially vertical with respect to a surface of the substrate; and
a sidewall of the N-type semiconductor material is substantially vertical with respect to the surface of the substrate.

17. A system comprising:
a circuit board;
a die;
a substrate having a first surface coupled to the circuit board and an opposing second surface coupled to the die;
a thermoelectric device comprising a P-type semiconductor material, a N-type semiconductor material, and a plurality of interconnect structures to transmit current from the circuit board and through the P-type and N-type semiconductor materials,
wherein the P-type semiconductor material and the N-type semiconductor material are at least in part embedded within the substrate, and
wherein the thermoelectric device has a first side proximal to the die, and a second side separated from the die by the first side.

18. The system of claim 17, further comprising:
a power supply system to supply power to the thermoelectric device; and
a wireless interface to facilitate communication between the system and another system,
wherein the die includes at least one of: a memory to store instructions, or a processor to execute the instructions,
wherein one or both the P-type semiconductor material or the N-type semiconductor material comprises at least one of: Tellurium (TE), or Bismuth (Bi), and
wherein the plurality of interconnect structures are inoperable to transmit current to or from the die.

19. A method comprising:
providing a layer of a substrate, the layer comprising dielectric material;
depositing a first thermoelectric material and a second thermoelectric material, wherein the first thermoelectric material and the second thermoelectric material are at least in part embedded within the substrate;
forming an interconnect structure that couples the first and second thermoelectric material; and
coupling a die to the substrate, wherein the die is coupled, through by the interconnect structure, to one or both: the first thermoelectric material or the second thermoelectric material.

20. The method of claim 19, wherein depositing the first thermoelectric material and the second thermoelectric material comprises:
forming a first recess and a second recess in the layer of substrate;
depositing the first thermoelectric material in the first recess; and
depositing the second thermoelectric material in the second recess.

21. The method of claim 19, wherein depositing the first thermoelectric material and the second thermoelectric material comprises:
forming a patterned dry film resist layer on the substrate;
depositing the first thermoelectric material through a first opening in the dry film resist layer, and the second thermoelectric material through a second opening in the film resist layer; and
removing the dry film resist layer.
